(19) United States
(12) Patent Application Publication
(10) Pub. No.: US 2022/0269838 A1
(43) Pub. Date: Aug. 25, 2022

(54) CONVERSATIONAL DESIGN BOT FOR SYSTEM DESIGN

(71) Applicant: Siemens Aktiengesellschaft, Munich (DE)

(72) Inventors: Heinrich Helmut Degen, Plainsboro, NJ (US); Arun Ramamurthy, Plainsboro, NJ (US); Yunsheng Zhou, Princeton, NJ (US)

(21) Appl. No.: 17/635,576

(22) PCT Filed: Aug. 14, 2020
(86) PCT No.: PCT/US2020/046297

§ 371 Date: Feb. 15, 2022

Related U.S. Application Data
(60) Provisional application No. 62/893,266, filed on Aug. 29, 2019.

(51) Int. Cl. G06F 30/20; G06N 5/02; G06F 9/451

(52) U.S. Cl. CPC G06F 30/20; G06N 5/025; G06F 9/451

(57) ABSTRACT

System and method for conversational dialog in an engineering systems design includes a design bot configured to generate a design dashboard on a graphical user interface that presents a textual representation of system design view information with a rendering of system design view components. A dialog box feature of the dashboard receives a plain text string conveying a user request for a system design view of system elements and properties of the system elements. The design bot translates plain text of the user request to a vectorized contextual user request using context defined for design activity goals with respect to elements of the system design. System design view information is retrieved from a design repository based on the vectorized user request. A plain text string response to the user request conveying system design information relevant to the system design is displayed in the dialog box.

### TECHNICAL FIELD

This application relates to engineering design software. More particularly, this application relates to a conversational design bot user interface for accessing and manipulating system design information managed by an engineering design software application.

### BACKGROUND

The purpose of Systems Engineering (including Software Engineering) is the design of a system, with its system architecture and system elements, which meets the defined system goals. Today, the process of designing such a system is highly manual and usually requires many iterations to meet objectives for the system. Part of the system design process can include a trade-off analysis for making informed design decisions on all architectural levels (e.g., system level, subsystem level, component level) to achieve the system objectives. In order to make such informed design decisions, access to various system design information is needed, such as system elements and their properties, referred to as a “system design view.”

Current systems are hindered by cumbersome access to system design views that pull information from documented system architecture and design. Typically, such system design views are structured by the decomposition principle of the system architecture. For instance, while within a single design domain, it is relatively easy to view a system element and its properties. However, if the system design process includes the systematic consideration of alternate system elements, the conventional way to access system design views has limitations. For example, a user must open different system designs, in the same or different system design tools (e.g., for Sys ML or for CyPhyML) to access a system design view of interest. It is a major manual effort, particularly requiring a user to leave the currently running system design tool, to compare system elements and their properties, or to select system elements with a “better” performance. Hence, a design process is hindered by inefficiency to view system elements and their properties particularly if the needed system view crosses different design domain boundaries. Furthermore, it is inefficient to compare competing system elements based on properties (e.g., “compare battery_1 with battery_2”, or “what is the best performing battery”). In conventional solutions, definition of system views of interest and comparison of system elements for selection, based on properties, is mostly an inefficient manual effort.

### SUMMARY

A system for engineering design provides a conversational design bot within the design space as an improvement to an engineering design interface. The design bot translates a user's request for a system design view, expressed via a text string (plain text input) or via a user's statement (voice input). System design view information is retrieved from a system design repository. The conversational design bot response is conveyed to the user as audio and/or textual statements using a dialogue box feature of a graphical user interface (GUI). The dialog box is integrated within a system design dashboard on the GUI, which includes a rendering of the system design view, and may also include properties and parameters of the retrieved system design view. The dialogue box may communicate with the user in the form of conversational dialog as plain text string and/or a voice conversation.

### BRIEF DESCRIPTION OF THE DRAWINGS

Non-limiting and non-exhaustive embodiments of the present embodiments are described with reference to the following FIGURES, wherein like reference numerals refer to like elements throughout the drawings unless otherwise specified.

FIG. 1 shows an example of a system for engineering design with a conversational design system in accordance with embodiments of this disclosure.

FIG. 2 shows an example of a configuration for a translator used for the conversational design system in accordance with embodiments of this disclosure.

FIG. 3 shows an example of dialog structure used for mapping contextualization in accordance with embodiments of the disclosure.

FIG. 4 shows a flowchart example of a conversational design bot operation in accordance with embodiments of this disclosure

FIG. 5 shows an example of a dashboard for an engineering system that integrates a conversational design bot according to embodiments of this disclosure.

FIG. 6 illustrates an example of a computing environment within which embodiments of the disclosure may be implemented.

### DETAILED DESCRIPTION

Methods and systems are disclosed for an engineering design system that integrates a conversational design bot into a design view dashboard for improved design efficiency. In a complex system design that involves contributions from engineers of multiple disciplines (e.g., electrical, mechanical, automation, etc.), while one engineer works within a respective design domain (or discipline), it is useful to have an awareness of the entire system, including the other domains, so that system-wide effects can be monitored as changes or additions in one design domain are implemented. In particular, the disclosed solution informs an engineer through a system design view for improved assessment of competing designs being considered within a single design domain. Unlike conventional engineering systems, the disclosed solution learns contextual information for the system components such that each component is represented as a virtual object linked to component characteristics made accessible to a user in various formats. In one of these formats, a conversational dialog system maps a user objective to a formal request for information and provides a display of the result enhanced with recommendations in a conversational format. Using a graphical user interface, a user may submit the request in a plain text string or by a voice command, such as “what is the best battery for design 212 of device Beta?” The system response may include a reference to an engineering design element by name (e.g., Battery_14) as a plain text string or an audio voice response, along with retrieval of the design element as an object accessible to the user on a visual display. The retrieved object can then be manipulated using a variety of object operations. The conversational dialog system solves technical problems, such as inefficient system design views of elements and element properties, particularly for instances of crossing boundaries of system elements, and resolving competing system design elements based on properties and performance. An advantage of the dialog interface is that a user query can be redirected by the system via one or more query/response exchanges, helping the user to focus the request to the most suitable form for retrieval of system information.

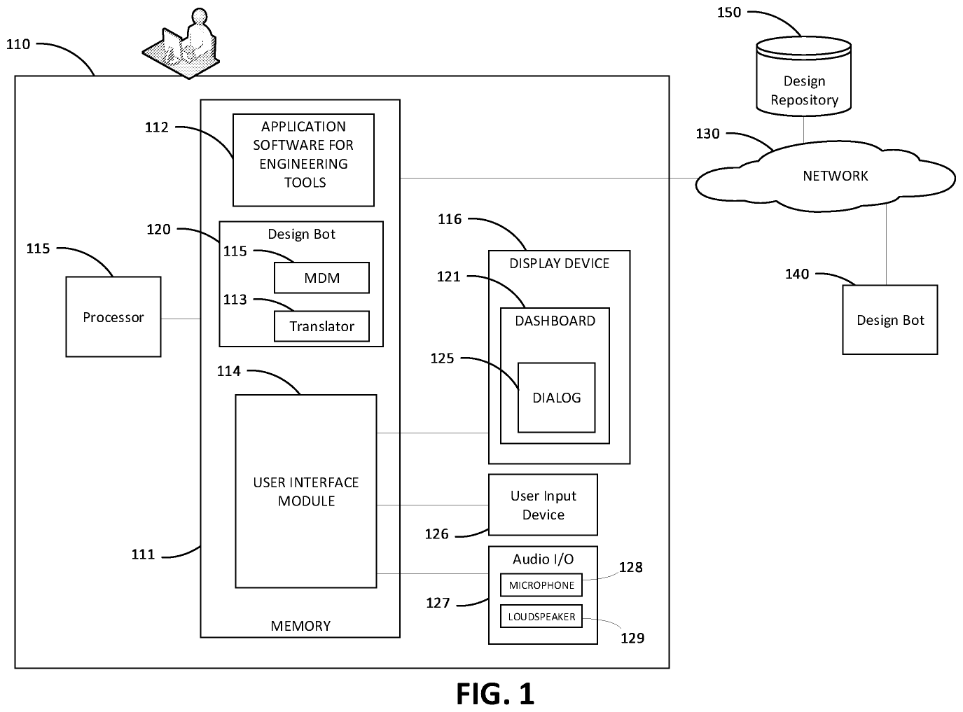

FIG. 1 shows an example of an engineering design system with an integrated conversational dialog system in accordance with embodiments of this disclosure. In an embodiment, a design engineering project is performed for a target object or system. A computing device 110 includes a processor 115 and memory 111 (e.g., a non-transitory computer readable media) on which is stored various computer applications, modules or executable programs. Engineering applications 112 may include software for one or more of modeling tools, a simulation engine, computer aided design (CAD) tools, and other engineering tools accessible to a user via a display device 116 and a user interface module 114 that drives the display feed for display device 116 and processes user inputs back to the processor 115, all of which are useful for performing computer aided design, such as in the form of 2D or 3D renderings of the physical design, and system design analysis, such as high-dimensional design space visualization of design parameters, performance parameters, and objectives. A network 130, such as a local area network (LAN), wide area network (WAN), or an internet based network, connects computing device 110 to a repository of design data 150.

In an embodiment, engineering data generated by application software for engineering tools 112 is monitored and organized into system design data stored by design repository 150. System design data are the accumulation of system elements and element properties exported from engineering tools 112 over the course of design projects and design revisions. In some embodiments, system design data of elements are obtained from a supplier, such as a vendor or manufacturer of components related to the system under design. For example, system design data may include technical design parameters, sensor signal information, operation range parameters (e.g., voltage, current, temperature, stresses, etc.). In instances of simulations performed by engineering tools 112, simulation result data may be attached to system design data for respective elements, which is useful for selection of competing design elements. As a practical example, battery performance for different batteries can be recorded over several simulations of various designs for a battery powered drone. In other aspects, tests and experiments of prototypes can yield system design data that can be attached to design elements in the system design data and stored in design repository 150. Hence, the design repository 150 may contain structured and static domain knowledge about various designs.

Design bot 120 is an algorithmic module configured to provide system design view information in various interactive formats accessible to the user, such as a user dashboard and a conversational design dialog that translates a user request for a design view expressed as a plain text string or a voice input to a formal request that is mappable to the system design data. In an embodiment, design bot 120 is installed as a local instance in memory 111 for interaction with the application software for engineering tools 112. Alternatively, the design bot implementation may be a cloud-based or web-based operation, shown as design bot module 140, or a divided operation shared by both design bot 120 and 140. Herein, for simplicity, the design bot configuration and functionality are described with reference to design bot 120, however, the same configuration and functionality applies to any embodiment implemented by the design bot 140. In an aspect, design bot 120 becomes an active interface for the user while one or more engineering tools 112 runs in the background, allowing the user to perform both inquiries and modifications to the design using a system design view. As such, design bot 120 allows a user to indirectly operate application software for engineering tools 112 through the graphical user interface generated by design bot 120. In an aspect, the design bot module 120 manages the engineering tools 112 operating in the background. For example, a user may interact directly with a graphical user interface (GUI) (presented to the user on display device 116 as design dialog box 125) of the design bot 120 for a request of design component analysis, the design bot 120 then communicates the request to the design space controlled by an engineering tool 112, which executes the analysis in the background and returns results back to the design both 120 that presents the results to the user through the GUI.

User interface module 114 provides an interface between the system application software modules 112, 120 and user devices such as display device 116, user input device(s) 126 (e.g., keyboard, touchscreen, and/or mouse) and audio I/O devices 127 (e.g., microphone 128, loudspeaker 129). Design dashboard 121 and design dialog box 125 are generated as an interactive GUI by design bot 120 during operation and rendered onto display device 116, such as a computer monitor or mobile device screen. User input device 126 receives user inputs in the form of plain text strings using a keyboard or other texting mechanism. User requests for design data can be submitted to the design bot 120 as a plain text string in the design dialog box 125 while viewing aspects of the system design on the design dashboard 121. Audio interface may be configured with a voice sensor (e.g., microphone) and a playback device (audio speaker). Vocal user requests can be received by audio I/O device 127 and processed by user interface module 114 for translation to a text string request, which may be displayed in the dialog box. Design bot 120 is configured to translate the text string request, map the request to system design data, and retrieve a design view from the design repository 150. From the retrieved data, design bot 120 extracts response information and generates a dialog response in the form of a plain text string for viewing in design dialog box 125, a voice response for audio play to the user on audio I/O device 127, or a combination of both. The design dashboard 121 is configured as graphical display of design view elements (e.g., a 2D or 3D rendering) with properties and metrics related to the design view elements generated by the engineering application 112.

Design bot 120 is configured for translation functionality using translator module 113 and multimodal dialog manager (MDM) 115, performing conversion of design space object context into conversational dialog and vice-versa. User inputs during the system design process are processed in a conversational form for an improved user experience, allowing the designer to explore and find design alternatives with reduced interaction complexity and cognitive load. An advantage of processing queries posted at the user interface in a conversational form eliminates the need for learning and/or memorizing a complex interaction language, reducing cognitive load for the designer. The translator module 113 comprises several components for processing inputs and outputs, depending on the modality.

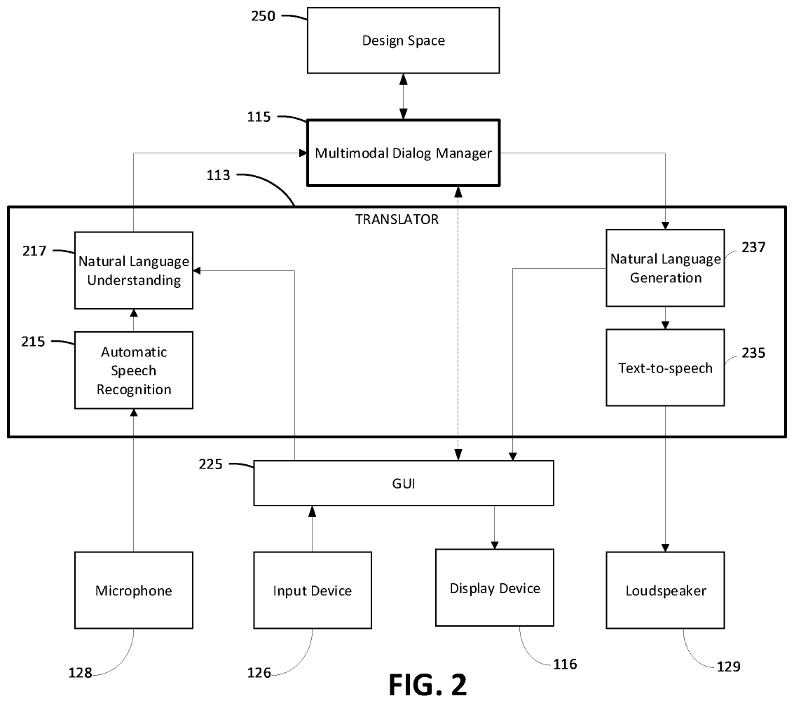

FIG. 2 shows an example of a configuration for a translator used for the conversational design system in accordance with embodiments of this disclosure. The operation of MDM 115 and translator 113 of FIG. 1 are shown in greater detail in FIG. 2. In an embodiment, translator module 113 comprises a plurality of components arranged to process voice and text dialog related to system design views. Voice commands received from microphone 128 are processed using an automatic speech recognition (ASR) component 215 (e.g., Kaldi) for converting voice commands to digital speech data and a natural language understanding (NLU) component 217 (e.g., NER, MME) configured to extract linguistic meaning of the user request from the digital text data. Voice responses are processed using natural language generation component 237 (e.g., template based generation) and text-to-speech component 235 for audio playback on loudspeaker 129. Textual inputs and outputs at devices 126, 116 tied to GUI 225 are translated by natural language understanding component 217 and natural language generation component 237. MDM 115 is configured to process complex dialogs for use in engineering design applications. The MDM processes the input based on the user input modality. For example, if the user input modality is voice, the MDM controls the translator 113 to process the voice command using both modalities of voice and text so that the dialog box can display the text of the voice dialog. The MDM exchanges information with the design space, retrieving requested information in response to submitted design view requests. In order to support complex dialogs, the MDM 115 constructs a dialog structure in a logical container as elements for mapping contextualization.

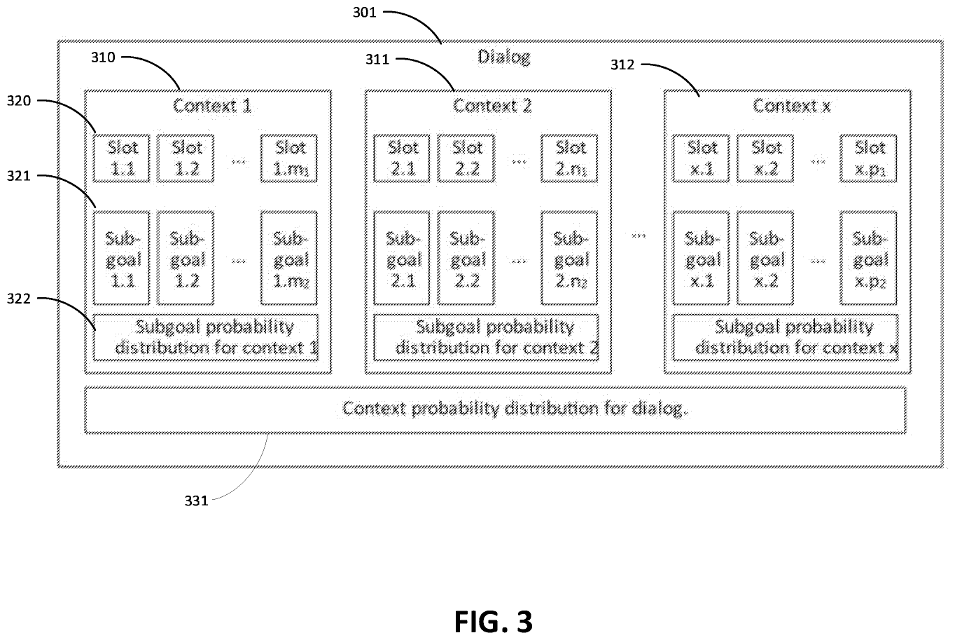

FIG. 3 shows an example of dialog structure used for mapping contextualization in accordance with embodiments of the disclosure. The design bot 120 is configured to translate a plain text user request to a vectorized contextual user request using context defined for design activity goals with respect to elements of the system design. A machine learning process may be implemented to extract the relevant context. In an embodiment, from a string of translated dialog received by the MDM 115 related to system design view data requests, a logical container 301 is constructed of all used contexts for a design application including contextual mappings 310, 311, 312 generated for Context 1, Context 2 . . . Context X. In an embodiment, the dialog structure construction is implemented using a machine learning process that records received data requests and predicts which design activity context it relates to, and which one or more goals or subgoals within the context, according to a probability distribution. In another embodiment, MDM 115 applies a rule-based algorithm to recognize (a) user intent, and/or (b) system entity, the rules being defined during system configuration according to known design components and expected user intent for defined design activity contexts. For example, a user intent rule may be defined as “if intent A is recognized or Context 1, then perform task 1A”; a system entity rule may be defined as “if entity=‘battery’ for Context 2, then perform task B.” Accordingly, a rule is selected by MDM 115 in response to a received user input.

Within each contextual mapping, the dialog elements (e.g., vector representation of words in a sentence of dialog) is divided into a vector of slot values 320 and subgoals 321. A subgoal 321 is an element in a context and reflects a single step of a use case, hence called “subgoal”. It is called “subgoal” and not “step” because the dialog does not enforce the sequence of steps. The user's intent can be assigned to any subgoal within one context. As an example, for the context “DesignSpaceExploration”, potential subgoals could be “GetRepresentationChanged” or “GetRewardChanged.” The subgoals 321 are assigned a subgoal probability distribution 322 for the respective context. A context probability distribution 331 is computed by MDM 115 for ranking the contextual mappings 310, 311, 312. Each context can be compared to a use case with a particular goal. Dialog steps are grouped according to which are likely to be used in a timely vicinity without losing the context of respective slot values. Each step of an overall system design workflow (e.g., design space construction, design composition, design space exploration) is assigned to a context. For example, for a design space exploration task, a context element, or subgoal, may reflect a single step of a use case. In an aspect, design space exploration context refers to a design activity of exploring change effects to the system design in response to one or more particular technical parameter changes. Design composition context involves determining whether a system design space for a first component is compatible with another component (e.g., applying design space distribution mapping). Design space construction context defines the limits to a design space. The dialog mapping does not enforce sequence steps, but rather user intent being assigned to any subgoal within one context. For example, in the context “Design Space Exploration”, potential subgoals could be “Get Representation Changed” or “Get Reward Changed”. Slot values are candidate values for each subgoal, and each slot value is global for a context, so the slot value can be shared among the subgoals of the same context. This avoids the user having to repeat information between different dialog steps. For a subgoal “GetRepresentationChanged”, potential slot values for Battery 1 capacity may be “4150 mAh”, “5100 mAh”, “5850 mAh”. For the subgoal “GetRewardChanged”, a potential slot values are: “cost” (show lowest cost first), “reliability” (show highest reliability first). The context probability distribution 331 for entire dialog specifies how likely that a context will be selected. Subgoal probability distribution 322 for each context specifies how likely that a subgoal will be selected. With the dialog structure 301, the MDM 115 (1) retains the context and reuses slot values, so that the interaction becomes more efficient; (2) supports mixed-initiate dialogs, however it can enforce a certain sequence of subgoal; (3) automatically clarifies unknown slot values; and (4) grounds slot values. To illustrate, the structure of a subgoal consists of the following elements (a) Input—defines the intent which is used to identify the subgoal; identifies the entities which are used in the subgoal; (b) Declaration—declares internal variables needed for the subgoal; (c) Clarification—requests missing entity values; (d) Grounding—If requested, the user is asked to confirm the slot value; (e) Output—selects response identifiers and response parameters, considering different modalities, selects action command(s) with action parameters, specifies the next context/subgoal and the previous context/subgoal with a probability, and selects the output modality.

Design bot 120 is configured to process various dialog types including the following examples:
Request support from another team member (e.g. Context: “TeamCollaboration”; subgoal: GetTeamMember; slot values: “Battery”, “Controller”, . . . )
Request to filter and sort designs (e.g., Context: “DesignSpaceExploration”; subgoal: “GetCompareDesign” with slot “DesignID” (slot values: 1,2,3) and slot “Attribute” (slot values: “performance”, “reliability”, “cost”, “durability”)
Request to compare designs (e.g., Context: “DesignSpaceExploration”; subgoal: “GetBestDesign”; slot “Attribute” and slot values “performance”, “reliability”, “cost”, “durability”, . . . )
Request for most constraining attributes (e.g., Context: “DesignComposition”; subgoal: “GetMostContrainingDesign”)

In an embodiment, when the requested system design view is retrieved from design repository 150, the vectorized request is compared to objects of the system design in the repository which are formatted as vectorized objects according to a common scheme and a match is determined by finding object vectors with shortest distance to the request vector. In an aspect, the stored system design information is configured as a knowledge graph with vectorized nodes. The comparison may be executed by applying an index lookup, where knowledge graph nodes are indexed by the vectors.

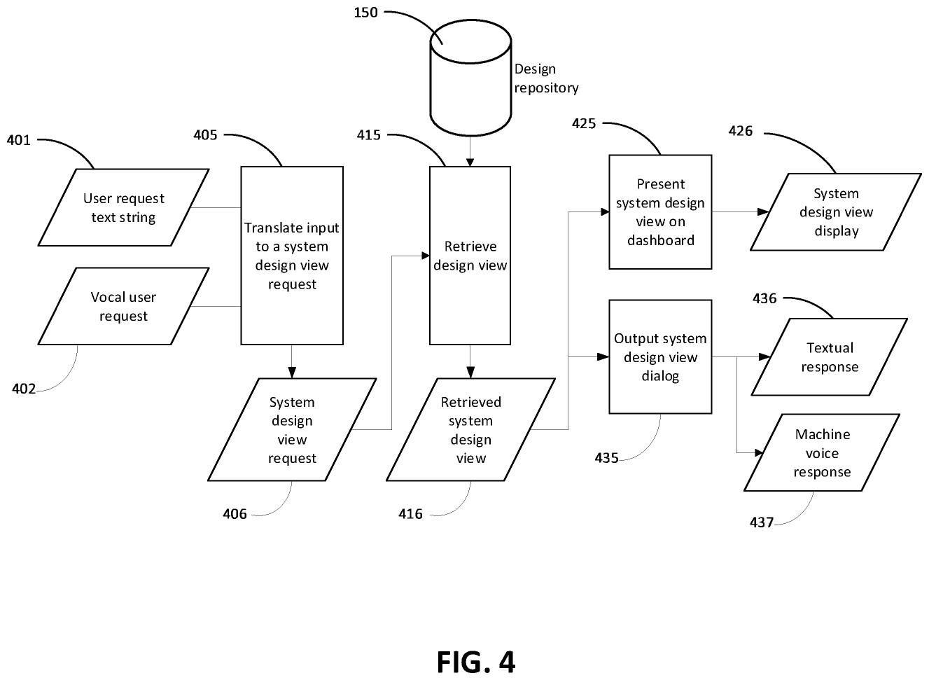

FIG. 4 shows a flowchart example of a conversational design bot operation in accordance with embodiments of this disclosure. User request plain text string 401 is entered in dialog box and received by the design bot 120 via user interface module 114 and translated 405 by translator module 113 and MDM 115 to a design view request 406 as described above. Alternatively, a vocal user request 402 is received at audio I/O device 127, processed by user interface module 114, and translated by translator module 113 and MDM 115. In an aspect, vocal requests are translated to a text string request using a translator algorithm and displayed in design dialog box for user feedback and confirmation of the received request. For example, an ASR component (e.g., Kaldi) is trained to learn domain specific expressions (e.g., design, component, performance, battery, etc.), and upon receiving a user utterance, it translates the voice to a text string.

At 415, the design bot 120 retrieves the design view information 416 from the design repository 150 based on the system design view request 406. Design bot 120 presents system design view with contextual objects on the dashboard at 425, in one or more formats, such as a graphical display 426 of system components. Design bot 120 also outputs system design view dialog at 435 as a textual response 436 in a dialog box 125 or a machine voice response 437 to audio I/O device 127, as a response to the user request 401, 402.

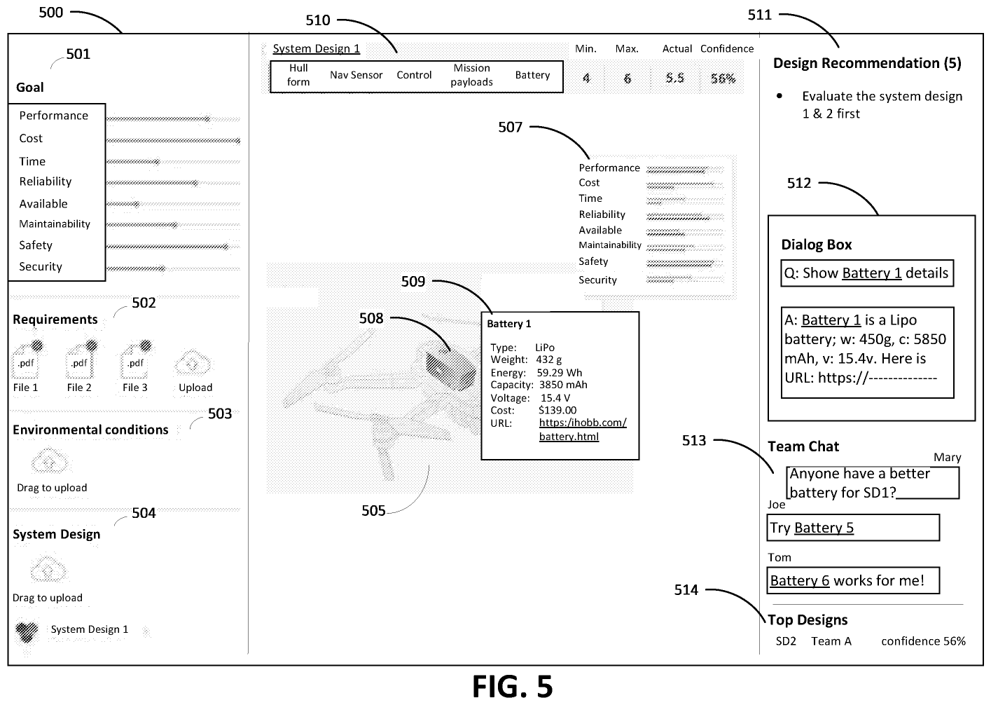

FIG. 5 shows an example of a dashboard with dialog box for an engineering system that integrates a design bot according to embodiments of this disclosure. Dashboard 500 is a graphical user interface that can be displayed to a user on a portion of a computer monitor for example. The functionality of the dashboard includes providing an interactive GUI for a user with system design view information that is most important to the engineering design activity, allowing design activities that normally take several hours with conventional means to be performed in a matter of minutes. For example, design parameters and design components can be rapidly swapped within the system design view because critical contextual information is instantly viewable for any target component. In an embodiment, dashboard 500 may be integrated with an engineering application 112 as a separate screen view that can be toggled on and off from an engineering tool used for the target design. Alternatively, the dashboard 500 may be displayed on a first portion of the screen alongside of one or more engineering tools being displayed on a second portion of the screen. As shown, dashboard screen portions may include design goals 501, design requirements 502, environmental condition files 503, system design files 504, visual system design view 505, design metrics 507, target component view 508, target component details 509, system design component bar 510, design recommendations 511, dialog box 512, team chat 513, and top ranked designs 514. Conversational dialog box 512 is part of the dashboard 500 display, allowing a user to type in a plain text string request for design view information, and to display a dialog response to the user with design view information extracted from the design repository, via the design bot operation. In addition to the dialog box feature, the design view is presented graphically as a system design 505 with the target component 508 related to the user design view request. For example, as shown, system design 1 relates to an electric quadrofoil drone shown by visual system design view 505, and the target component 508 is a rendered battery related to the current session in dialog box 512. In an embodiment, the design bot 120 generates the dashboard 500 with contextual information for system design view objects, whereby components, such as Battery 1 shown in FIG. 5, are displayed in text with a contextual indicator (e.g., bold, special color, underlined) to indicate to the user that contextual information is accessible for this component. For example, the contextual information for Battery 1 is presented in the dialog box 512 answer block as a textual string, and as an overlay in the visual system design view, shown as target component details 509. In addition, as any object is referenced within dialog box 512 (e.g., Battery 1), team chat portion 513 (e.g., Battery 5, Battery 6), or elsewhere in the dashboard 500, the object is displayed with the contextual indicator (e.g., underlined, highlighted, bold text, or the like) allowing the user to manipulate the object in various ways. For example, the object Battery 5 in team chat 513 can be dragged into the visual system design view 505, and the design bot 120 will integrate the different battery into the system design, including updating the dashboard 500 with the target component display 508 and details 509 for Battery 5.

The Goal portion 501 in dashboard 500 is an interactive display of technical design parameters allowing a user to input parameter settings for the system design, and recording the settings in a visual manner, such as slide bars shown in FIG. 5 which can be adjusted using a pointer device (e.g., mouse or via touch screen). Requirement files 502 are present on dashboard 500 to indicate the currently uploaded files containing design requirements for the active system design. Environmental condition files 503 portion of dashboard 500 shows currently uploaded files for the system design as input for system design analysis, such as expected environmental conditions in which the system design may encounter and will be required to perform satisfactorily. System design files 504 shows currently uploaded system design files containing the data for various system designs accessible to the user through dashboard 500. Visual system design view 505 provides a visual rendering of the entire system design configuration including all components identified in component bar 510. The target component being the topic of dialog box 512 is presented visually as rendered target component 508 and a display of component properties 509, which may include, but is not limited to: type, weight, energy, capacity, voltage, cost and a URL link for further information.

The design bot 120 and dialog app 125 work together to form a conversational dialog system that translates a user's objective, submitted in the form of a request within a conversational dialog, to a system design view request in the form of a contextual goal or subgoal for a design activity. Table 1 provides a non-limiting set of examples for system design view request translations.

TABLE 1

| User request | Goal/Subgoal |
|---|---|
| “show system design 1”, “show battery 1” | One system or system element |
| “show me the details of the selected battery” | Details |
| “most reliable system design”, “most reliable battery” | Property filter |
| “show me all batteries” | All options |
| “show me the battery with the shortest charging time” | Select one out of several |
| | options via criteria |
| “difference between battery 1 and battery 2, “key differences | Compare |
| between system design 1 and system design 2” | |
| “met requirements of battery 1”, “unmet requirements of | Met or unmet goals/ |
| battery 1”, “met goals of system design 1”, “unmet goals of | requirements |
| system design 1” | |
| “show the best three system design”, “show the best system | Ranking |
| design”, “show the best battery”, “show the best three | |
| batteries” | |
| “properties added by the design exploration” | Machine added properties |
| “system elements added by the design exploration” | Machine added system |
| | elements |
| “how to improve battery 1”, “how to improve system design | Design gap |
| 1” | |
| “systems with the highest risks”, “systems with the lowest | Risks |
| risks” | |
| “team, we need a better battery than battery 1” | Request system |
| | elements |
| “team, please review battery 1”, “team please review system | Ask team to comment a |
| design 1” | system design/element |
| “assign system design 1 to ranking”, “remove system 1 from | Assign/remove system design |
| ranking” | on ranking list |
| “look for other battery designs”, “look for other system | New designs |
| designs” | |
| “reduce system reliability by 0.1%”, “increase the weight of | Change properties/goals |
| the battery by 100 gram” | |
| “what's the next step” | Design advise |
| “replace battery with Battery 2” | Design command |

When the conversational dialog system responds with a reference to a system element (e.g. “system design 1”, “Battery 1”), the system element is accessible as an object, and can be handled as an object, including, but not limited to the following object operations: view, open, close, save, save as, send, share, move, cut'n'paste, copy'n'paste, delete, modify, rank, sort, drag'n'drop. For example, as shown in FIG. 5, system element Battery 1 can be handled as an object, and by a selection operation (e.g., point and click with a computer mouse), details and characteristics are viewed as target object details 509, and a visual representation is viewed as target component view 508.

System design view responses to requests can be in various forms, depending on the context of the request. For example, the dashboard may display one or more of the following: performance and attributes of a target component and/or the system can be displayed on the dashboard, a visual display of the system zoomed in at the target component, plot of power consumption over time.

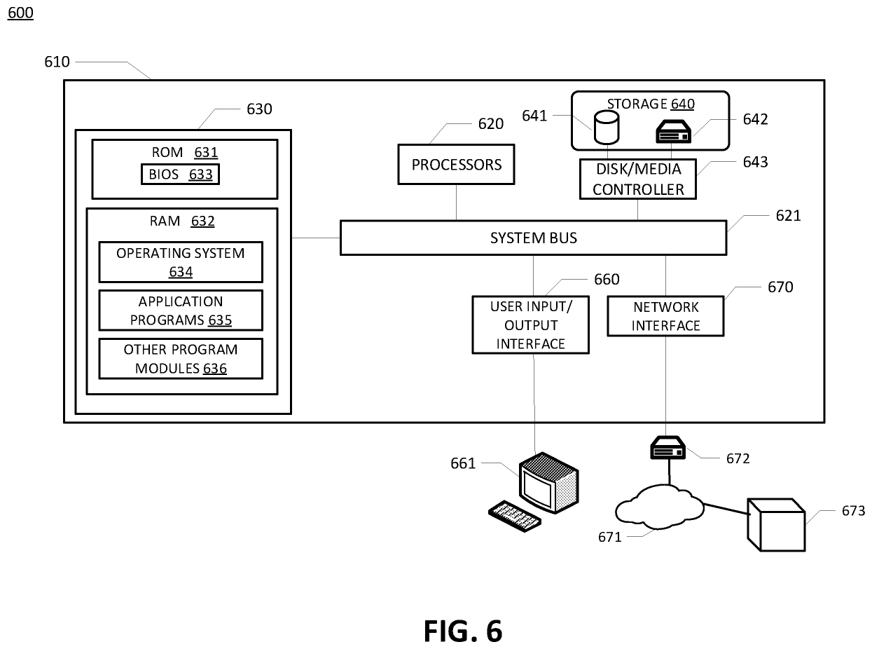

FIG. 6 illustrates an example of a computing environment within which embodiments of the present disclosure may be implemented. A computing environment 600 includes a computer system 610 that may include a communication mechanism such as a system bus 621 or other communication mechanism for communicating information within the computer system 610. The computer system 610 further includes one or more processors 620 coupled with the system bus 621 for processing the information. In an embodiment, computing environment 600 corresponds to an engineering design system with a conversational dialog feature for efficient design development, in which the computer system 610 relates to a computer described below in greater detail.

The processors 620 may include one or more central processing units (CPUs), graphical processing units (GPUs), or any other processor known in the art. More generally, a processor as described herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a computer, controller or microprocessor, for example, and be conditioned using executable instructions to perform special purpose functions not performed by a general purpose computer. A processor may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) 620 may have any suitable microarchitecture design that includes any number of constituent components such as, for example, registers, multiplexers, arithmetic logic units, cache controllers for controlling read/write operations to cache memory, branch predictors, or the like. The microarchitecture design of the processor may be capable of supporting any of a variety of instruction sets. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

The system bus 621 may include at least one of a system bus, a memory bus, an address bus, or a message bus, and may permit exchange of information (e.g., data (including computer-executable code), signaling, etc.) between various components of the computer system 610. The system bus 621 may include, without limitation, a memory bus or a memory controller, a peripheral bus, an accelerated graphics port, and so forth. The system bus 621 may be associated with any suitable bus architecture including, without limitation, an Industry Standard Architecture (ISA), a Micro Channel Architecture (MCA), an Enhanced ISA (EISA), a Video Electronics Standards Association (VESA) architecture, an Accelerated Graphics Port (AGP) architecture, a Peripheral Component Interconnects (PCI) architecture, a PCI-Express architecture, a Personal Computer Memory Card International Association (PCMCIA) architecture, a Universal Serial Bus (USB) architecture, and so forth.

Continuing with reference to FIG. 6, the computer system 610 may also include a system memory 630 coupled to the system bus 621 for storing information and instructions to be executed by processors 620. The system memory 630 may include computer readable storage media in the form of volatile and/or nonvolatile memory, such as read only memory (ROM) 631 and/or random access memory (RAM) 632. The RAM 632 may include other dynamic storage device(s) (e.g., dynamic RAM, static RAM, and synchronous DRAM). The ROM 631 may include other static storage device(s) (e.g., programmable ROM, erasable PROM, and electrically erasable PROM). In addition, the system memory 630 may be used for storing temporary variables or other intermediate information during the execution of instructions by the processors 620. A basic input/output system 633 (BIOS) containing the basic routines that help to transfer information between elements within computer system 610, such as during start-up, may be stored in the ROM 631. RAM 632 may contain data and/or program modules that are immediately accessible to and/or presently being operated on by the processors 620. System memory 630 may additionally include, for example, operating system 634, application modules 635, and other program modules 636. Application modules 635 may include aforementioned modules described for FIG. 1 or FIG. 2 and may also include a user portal for development of the application program, allowing input parameters to be entered and modified as necessary.

The operating system 634 may be loaded into the memory 630 and may provide an interface between other application software executing on the computer system 610 and hardware resources of the computer system 610. More specifically, the operating system 634 may include a set of computer-executable instructions for managing hardware resources of the computer system 610 and for providing common services to other application programs (e.g., managing memory allocation among various application programs). In certain example embodiments, the operating system 634 may control execution of one or more of the program modules depicted as being stored in the data storage 640. The operating system 634 may include any operating system now known or which may be developed in the future including, but not limited to, any server operating system, any mainframe operating system, or any other proprietary or non-proprietary operating system.

The computer system 610 may also include a disk/media controller 643 coupled to the system bus 621 to control one or more storage devices for storing information and instructions, such as a magnetic hard disk 641 and/or a removable media drive 642 (e.g., floppy disk drive, compact disc drive, tape drive, flash drive, and/or solid state drive). Storage devices 640 may be added to the computer system 610 using an appropriate device interface (e.g., a small computer system interface (SCSI), integrated device electronics (IDE), Universal Serial Bus (USB), or FireWire). Storage devices 641, 642 may be external to the computer system 610.

The computer system 610 may include a user input/output interface module 660 to process user inputs from user input devices 661, which may comprise one or more devices such as a keyboard, touchscreen, tablet and/or a pointing device, for interacting with a computer user and providing information to the processors 620. User interface module 660 also processes system outputs to user display devices 662, (e.g., via an interactive GUI display).

The computer system 610 may perform a portion or all of the processing steps of embodiments of the invention in response to the processors 620 executing one or more sequences of one or more instructions contained in a memory, such as the system memory 630. Such instructions may be read into the system memory 630 from another computer readable medium of storage 640, such as the magnetic hard disk 641 or the removable media drive 642. The magnetic hard disk 641 and/or removable media drive 642 may contain one or more data stores and data files used by embodiments of the present disclosure. The data store 640 may include, but are not limited to, databases (e.g., relational, object-oriented, etc.), file systems, flat files, distributed data stores in which data is stored on more than one node of a computer network, peer-to-peer network data stores, or the like. Data store contents and data files may be encrypted to improve security. The processors 620 may also be employed in a multi-processing arrangement to execute the one or more sequences of instructions contained in system memory 630. In alternative embodiments, hard-wired circuitry may be used in place of or in combination with software instructions. Thus, embodiments are not limited to any specific combination of hardware circuitry and software.

As stated above, the computer system 610 may include at least one computer readable medium or memory for holding instructions programmed according to embodiments of the invention and for containing data structures, tables, records, or other data described herein. The term “computer readable medium” as used herein refers to any medium that participates in providing instructions to the processors 620 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 641 or removable media drive 642. Non-limiting examples of volatile media include dynamic memory, such as system memory 630. Non-limiting examples of transmission media include coaxial cables, copper wire, and fiber optics, including the wires that make up the system bus 621. Transmission media may also take the form of acoustic or light waves, such as those generated during radio wave and infrared data communications.

Computer readable medium instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, may be implemented by computer readable medium instructions.

The computing environment 600 may further include the computer system 610 operating in a networked environment using logical connections to one or more remote computers, such as remote computing device 673. The network interface 670 may enable communication, for example, with other remote devices 673 or systems and/or the storage devices 641, 642 via the network 671. Remote computing device 673 may be a personal computer (laptop or desktop), a mobile device, a server, a router, a network PC, a peer device or other common network node, and typically includes many or all of the elements described above relative to computer system 610. When used in a networking environment, computer system 610 may include modem 672 for establishing communications over a network 671, such as the Internet. Modem 672 may be connected to system bus 621 via user network interface 670, or via another appropriate mechanism.

Network 671 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 610 and other computers (e.g., remote computing device 673). The network 671 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 671.

It should be appreciated that the program modules, applications, computer-executable instructions, code, or the like depicted in FIG. 6 as being stored in the system memory 630 are merely illustrative and not exhaustive and that processing described as being supported by any particular module may alternatively be distributed across multiple modules or performed by a different module. In addition, various program module(s), script(s), plug-in(s), Application Programming Interface(s) (API(s)), or any other suitable computer-executable code hosted locally on the computer system 610, the remote device 673, and/or hosted on other computing device(s) accessible via one or more of the network(s) 671, may be provided to support functionality provided by the program modules, applications, or computer-executable code depicted in FIG. 6 and/or additional or alternate functionality. Further, functionality may be modularized differently such that processing described as being supported collectively by the collection of program modules depicted in FIG. 6 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 6 may be implemented, at least partially, in hardware and/or firmware across any number of devices.

It should further be appreciated that the computer system 610 may include alternate and/or additional hardware, software, or firmware components beyond those described or depicted without departing from the scope of the disclosure. More particularly, it should be appreciated that software, firmware, or hardware components depicted as forming part of the computer system 610 are merely illustrative and that some components may not be present or additional components may be provided in various embodiments. While various illustrative program modules have been depicted and described as software modules stored in system memory 630, it should be appreciated that functionality described as being supported by the program modules may be enabled by any combination of hardware, software, and/or firmware. It should further be appreciated that each of the above-mentioned modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular module may, in various embodiments, be provided at least in part by one or more other modules. Further, one or more depicted modules may not be present in certain embodiments, while in other embodiments, additional modules not depicted may be present and may support at least a portion of the described functionality and/or additional functionality. Moreover, while certain modules may be depicted and described as sub-modules of another module, in certain embodiments, such modules may be provided as independent modules or as sub-modules of other modules.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A system for conversational dialog in engineering systems design, comprising:
a processor; and
a memory having stored thereon modules executed by the processor, the modules comprising:
a design bot configured to generate a design dashboard on a graphical user interface that presents a textual representation of system design view information with a rendering of system design view components, the dashboard comprising:
a dialog box feature configured to receive a plain text string conveying a user request for a system design view, the system design view comprising a view of system elements and properties of the system elements;
wherein the design bot is further configured to:
translate the plain text of the user request to a vectorized contextual user request using context defined for design activity goals with respect to elements of the system design, wherein the vectorized contextual user request extracts relevant context based on machine learning of previous user requests;
retrieve system design view information from a design repository; and
generate a plain text string response to the user request conveying system design information relevant to the system design, the plain text response displayed in the dialog box.

2. The system of claim 1, wherein information stored in the design repository is formatted as vectorized objects, wherein the design bot is further configured to retrieve the system design information by comparing the vectorized user request with vectorized objects and retrieving objects with shortest distance to the vectorized request.

3. The system of claim 1, wherein the dialog box feature is configured to receive a voice command conveying a user request for a system design view, the system further comprising:
an automatic speech recognition component configured to convert the voice command to digital text data; and
a natural language understanding component configured to extract linguistic meaning of the user request from the digital text data;
wherein the design bot is further configured to retrieve the system design view data based on the linguistic meaning of the user request.

4. The system of claim 3, further comprising:
a multimodal dialog manager configured to construct a dialog structure in a logical container as elements for mapping contextualization using a machine learning process that records received data requests and predicts which design activity context relates to the respective data request according to a probability distribution.

5. The system of claim 4, wherein the dialog structure comprises:
a set of contexts, each context representing a design activity context, wherein each context groups a set of subgoals, each subgoal being an element in a context and reflecting a single step of a use case, and each context comprising a set of slot values as candidate values for each subgoal, the slot values being global for the context for sharing among the subgoals of the same context.

6. The system of claim 5, wherein the dialog structure further comprises:
for each context, a subgoal probability distribution specifying how likely for each subgoal in the context is to be selected.

7. The system of claim 5, wherein the dialog structure further comprises:
a context probability distribution for the entire dialog structure specifying how likely that any one context is to be selected.

8. The system of claim 3, further comprising:
a multimodal dialog manager configured to construct a dialog structure in a logical container as elements for mapping contextualization using a rule-based learning process that records received data requests and applies defined rules based on recognized user intent or system entity.

9. A computer implemented method for conversational dialog in engineering systems design, comprising:
generating a design dashboard on a graphical user interface that presents a textual representation of system design view information with a rendering of system design view components, the dashboard comprising a dialog box for displaying a conversational dialog between the user and engineering design software;
receiving a plain text string in the dialog box conveying a user request for a system design view, the system design view comprising a view of system elements and properties of the system elements;
translating the plain text of the user request to a vectorized contextual user request using context defined for design activity goals with respect to elements of the system design, wherein the vectorized contextual user request extracts relevant context based on machine learning of previous user requests;
retrieving system design view information from a design repository; and
generating a plain text string response to the user request conveying system design information relevant to the system design, the plain text response displayed in the dialog box.

10. The method of claim 9, wherein information stored in the design repository is formatted as vectorized objects, the method further comprising:
retrieving the system design information by comparing the vectorized user request with vectorized objects and retrieving objects with shortest distance to the vectorized request.

11. The method of claim 9, wherein the dialog box feature is configured to receive a voice command conveying a user request for a system design view, the system further comprising:
converting the voice command to digital text data; and
extracting linguistic meaning of the user request from the digital text data;
retrieving the system design view data based on the linguistic meaning of the user request.

12. The method of claim 11, further comprising:
constructing a dialog structure in a logical container as elements for mapping contextualization using a machine learning process that records received data requests and predicts which design activity context relates to the respective data request according to a probability distribution.

13. The method of claim 12, wherein the dialog structure comprises:
a set of contexts, each context representing a design activity context, wherein each context groups a set of subgoals, each subgoal being an element in a context and reflecting a single step of a use case, and each context comprising a set of slot values as candidate values for each subgoal, the slot values being global for the context for sharing among the subgoals of the same context.

14. The method of claim 13, wherein the dialog structure further comprises:
for each context, a subgoal probability distribution specifying how likely for each subgoal in the context is to be selected.

15. The method of claim 13, wherein the dialog structure further comprises:
a context probability distribution for the entire dialog structure specifying how likely that any one context is to be selected.
